(19) United States
(12) Patent Application Publication
(10) Pub. No.: US 2011/0110752 A1
(43) Pub. Date: May 12, 2011

(54) VACUUM PROCESSING SYSTEM AND VACUUM PROCESSING METHOD OF SEMICONDUCTOR PROCESSING SUBSTRATE

(75) Inventors: Susumu TAUCHI, Shunan-shi (JP); Hideaki Kondo, Kudamatsu-shi (JP); Teruo Nakata, Yokohama-shi (JP); Keita Nogi, Tokyo (JP); Atsushi Shimoda, Hiratsuka-shi (JP); Takafumi Chida, Chigasaki-shi (JP)

(73) Assignee: Hitachi High-Technologies Corporation

(21) Appl. No.: 12/883,602

(22) Filed: Sep. 16, 2010

(30) Foreign Application Priority Data
Nov. 12, 2009 (JP) 2009-258492

(51) Int. Cl. H01L 21/677

(52) U.S. Cl. 414/217

(57) ABSTRACT

The invention provides a vacuum processing system of a semiconductor processing substrate and a vacuum processing method using the same, comprising an atmospheric transfer chamber having a plurality of cassette stands, a lock chamber arranged on a rear side of the atmospheric transfer chamber, and a first vacuum transfer chamber connected to a rear side of the lock chamber, wherein the first vacuum transfer chamber does not have any vacuum processing chamber connected thereto and has transfer intermediate chambers connected thereto, and the transfer intermediate chambers have subsequent vacuum transfer chambers connected thereto, and wherein the wafers are transferred via the lock chamber to the first vacuum transfer chamber to be processed in each of the subsequent vacuum processing chambers, which are further transferred via any of the transfer intermediate chambers connected to the first vacuum transfer chamber to the subsequent vacuum transfer chambers, and the respective wafers transferred to the subsequent vacuum transfer chambers other than the first vacuum transfer chamber are transferred to the respective vacuum processing chambers connected to each of the vacuum processing chambers and processed therein.

The present application is based on and claims priority of Japanese patent application No. 2009-258492 filed on Nov. 12, 2009, the entire contents of which are hereby incorporated by reference.

### BACKGROUND OF THE INVENTION

### 1. Field of the Invention

The present invention relates to the arrangement of a vacuum processing system having a transfer mechanism of a semiconductor processing substrate (including semiconductor wafers and other substrate-like samples, hereinafter simply referred to as a “wafer”) disposed between vacuum processing chambers and vacuum transfer chambers of a semiconductor processing apparatus, and a vacuum processing method using this system. Especially, the present invention relates to the arrangement of a vacuum processing system having a plurality of vacuum processing chambers connected in series via transfer mechanisms disposed within a plurality of vacuum transfer chambers, and a vacuum processing method using the same.

2. Description of the Related Art

In the art related to the above-described type of apparatuses, especially apparatuses for processing objects within a decompressed chamber, there are demands for enhancing the microfabrication and precision of the process, and for enhancing the processing efficiency of the substrate to be processed. In response to such demands, there has been developed a multiple chamber apparatus in which a plurality of vacuum processing chambers are disposed in a single apparatus, according to which the production efficiency per footprint within a clean room has been improved.

According to such apparatus equipped with a plurality of vacuum processing chambers and other chambers used for processing, the gas and the pressure in the interior of the vacuum processing chambers or other chambers are controlled in a decompressable manner, and the chambers are connected to a vacuum transfer chamber having a robot arm or the like for transferring the substrates being processed.

According to such arrangement, the size of the whole body of the vacuum processing chamber is determined by the size, the number and the arrangement of the vacuum transfer chambers and the vacuum processing chambers. The arrangement of the vacuum transfer chambers is determined by the vacuum transfer chambers disposed adjacent thereto or the number of vacuum processing chambers connected thereto, the turning radius of the transfer robot disposed therein, the wafer size, and so on. Further, the arrangement of the vacuum processing chambers is determined by the wafer size, the vacuum efficiency, or the arrangement of devices required for wafer processing. Further, the arrangement of the vacuum transfer chambers and the vacuum processing chambers is also determined by the number of processing chambers required for the process or the maintenance performances thereof.

Regarding the above demands, patent document 1 (International publication of International Application published under the patent cooperation treaty No. 2007-511104) discloses methods and systems for handling workpieces in a vacuum-based semiconductor handling system, including methods and systems for handling materials from arm to arm in order to traverse a linear handling system. The disclosure of patent document 1 aims at solving the problems of a linear tool while answering to the demands for realizing a semiconductor processing apparatus capable of overcoming the restrictions specific to a cluster tool, to thereby provide a vacuum processing system capable of having wafers transferred therein with a small footprint.

### SUMMARY OF THE INVENTION

The above-mentioned prior art aims at providing a method and system for transferring wafers, but the following problems were not sufficiently considered.

The prior art lacked to consider the number and relationship of arrangement of the units constituting the vacuum processing system, which are vacuum transfer chambers for transferring wafers in vacuum and the vacuum processing chambers for processing wafers as the objects to be processed, so that the production efficiency thereof is optimized. As a result, the productivity per footprint of the apparatus was not optimized.

According to the prior art in which the productivity per footprint is not sufficiently considered, the wafer processing ability per footprint of the apparatus constituting the vacuum processing system had been deteriorated.

Therefore, the object of the present invention is to provide a vacuum processing system and a vacuum processing method for semiconductor substrates in which a high productivity per footprint is realized.

In order to solve the problems mentioned above, the present invention provides a vacuum processing system of a semiconductor processing substrate comprising an atmospheric transfer chamber having a plurality of cassette stands arranged on a front side thereof for transferring a wafer stored in a cassette disposed on one of the plurality of cassette stands; a lock chamber arranged on a rear side of the atmospheric transfer chamber for storing in an interior thereof the wafer transferred from the atmospheric transfer chamber; and a first vacuum transfer chamber connected to a rear side of the lock chamber to which the wafer from the lock chamber is transferred; wherein the first vacuum transfer chamber does not have any vacuum processing chamber connected thereto for processing wafers transferred to the first vacuum transfer chamber and has a plurality of transfer intermediate chambers connected thereto, and the plurality of transfer intermediate chambers have subsequent vacuum transfer chambers connected thereto; and wherein the wafers stored in the cassette are transferred from the cassette via the lock chamber to the first vacuum transfer chamber to be processed in each of the subsequent vacuum processing chambers, which are further transferred via any of the plurality of transfer intermediate chambers connected to the first vacuum transfer chamber to the plurality of subsequent vacuum transfer chambers, and the respective wafers transferred to the plurality of subsequent vacuum transfer chambers other than the first vacuum transfer chamber are transferred to the respective vacuum processing chambers connected to each of the plurality of vacuum transfer chambers and processed therein.

The present invention further provides a vacuum processing system of a semiconductor processing substrate, wherein only a single vacuum processing chamber is connected to each of the plurality of subsequent vacuum transfer chambers.

Moreover, the present invention provides a vacuum processing system of a semiconductor processing substrate, wherein transfer robots are disposed in the interior of each of the respective first and subsequent vacuum transfer chambers, and each transfer robot is composed of a plurality of arms having beam members as multiple joints capable of moving independently around respective axes.

Even further, the present invention provides a vacuum processing method of a semiconductor processing substrate for processing a semiconductor processing substrate using a vacuum processing system of a semiconductor processing substrate comprising: an atmospheric transfer chamber having a plurality of cassette stands arranged on a front side thereof for transferring a wafer stored in a cassette disposed on one of the plurality of cassette stands; a lock chamber arranged on a rear side of the atmospheric transfer chamber for storing in an interior thereof the wafer transferred from the atmospheric transfer chamber; and a first vacuum transfer chamber connected to a rear side of the lock chamber to which the wafer from the lock chamber is transferred; wherein the first vacuum transfer chamber does not have any vacuum processing chamber connected thereto for processing wafers transferred to the first vacuum transfer chamber and has a plurality of transfer intermediate chambers connected thereto, and the plurality of transfer intermediate chambers have subsequent vacuum transfer chambers connected thereto; and wherein the vacuum processing method of the semiconductor processing substrate comprises transferring wafers stored in the cassette to a the lock chamber, transferring the wafers transferred into the lock chamber to the first vacuum transfer chamber, and further transferring the same to each of the plurality of subsequent vacuum transfer chambers via any of the plurality of transfer intermediate chambers connected subsequently to the first vacuum transfer chamber, and thereafter, transferring the respective wafers transferred to the plurality of vacuum transfer chambers to the respective vacuum processing chambers each connected to the respective vacuum transfer chambers for processing the respective wafers.

The present invention enables to provide a vacuum processing system and a vacuum processing method of a semiconductor processing substrate, having a high productivity per footprint.

Further, the present invention enables to provide a vacuum processing system and a vacuum processing method of a semiconductor processing substrate capable of suppressing the amount of generated particles and preventing the occurrence of cross-contamination.

### BRIEF DESCRIPTION OF THE DRAWINGS

FIG. 1 is an explanatory view showing an outline of the overall arrangement of a vacuum processing system including a vacuum processing apparatus according to a first embodiment of the present invention;

FIG. 2A is an enlarged view showing the vacuum transfer chamber according to the embodiment illustrated in FIG. 1, wherein the robot arm is retracted;

FIG. 2B is an enlarged view showing the vacuum transfer chamber according to the embodiment illustrated in FIG. 1, wherein the robot arm is extended; and

FIG. 3 is an explanatory view showing an outline of the overall arrangement of the whole vacuum processing system including the vacuum processing apparatus according to another embodiment of the present invention.

### DETAILED DESCRIPTION OF THE PREFERRED EMBODIMENTS

Now, the preferred embodiments of a vacuum processing system and a vacuum processing method for processing a semiconductor substrate according to the present invention will be described in detail with reference to the drawings.

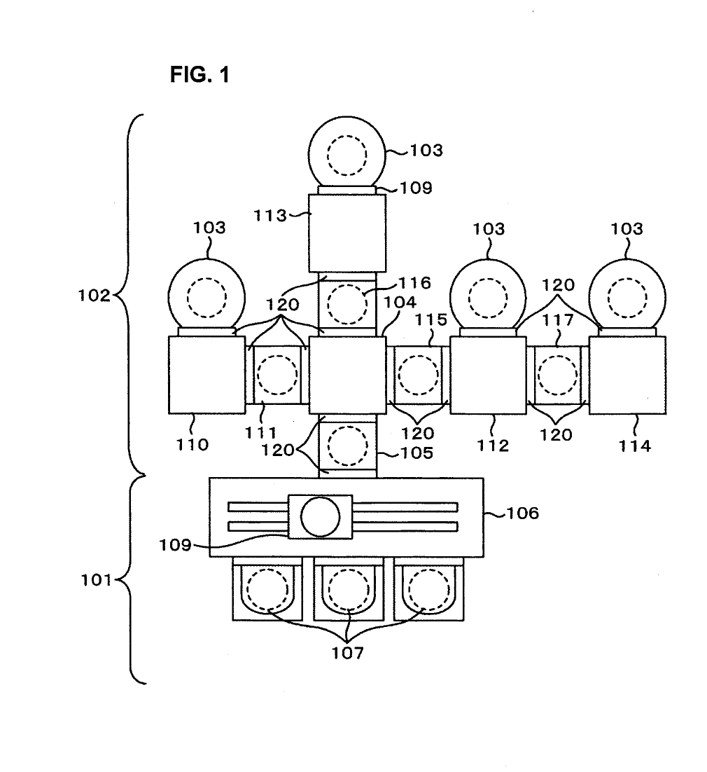

FIG. 1 illustrates an outline of the overall arrangement of the vacuum processing system including a plurality of vacuum processing chambers 103, 103, 103 and 103 according to a first embodiment of the present invention.

A vacuum processing system 100 including four vacuum processing chambers 103, 103, 103 and 103 according to a first preferred embodiment of the present invention shown in FIG. 1 is mainly composed of an atmospheric block 101 and a vacuum block 102. The atmospheric block 101 is a section for transferring in atmospheric pressure and determining the storage positions of semiconductor wafers as objects to be processed, and the vacuum block 102 is a block for transferring wafers in a pressure decompressed from atmospheric pressure and for processing the wafers in the predetermined vacuum processing chamber 103. The system 100 also comprises a lock chamber 105 in which the pressure is increased and decreased between atmospheric pressure and vacuum pressure while having a wafer stored therein, which is disposed between the vacuum block 102 for transferring and processing wafers and the atmospheric block 101.

The first preferred embodiment of the vacuum processing system 100 according to the present invention relates to a system configuration having a high productivity per footprint, wherein the number of vacuum processing chambers 103 is four and the transfer time in the vacuum block 102 is longer compared to the transfer time in the atmospheric block 101. According further to the present embodiment, the time required for processing a wafer in the vacuum processing chamber 103 or the stay time of the wafer in the vacuum processing chamber 103 is shorter than the time required for transferring the wafer. Based on these conditions, the overall processing time is restricted by the transferring process, and this state is called a limited transfer rate.

The atmospheric block 101 has a substantially rectangular solid shaped housing 106 storing an atmospheric transfer robot 109 therein, and on the front side of the housing 106 are disposed a plurality of cassette stands 107, 107 and 107. Cassettes storing wafers as objects to be processed or wafers for cleaning the vacuum processing chamber 103 are placed on multiple cassette stands 107, 107 and 107.

A single lock chamber 105 is disposed adjacent to the atmospheric block 101 in the vacuum block 102. The lock chamber 105 is disposed between a first vacuum transfer chamber 104 of the vacuum block 102 and the atmospheric block 101, for varying the inner pressure thereof between atmospheric pressure and vacuum pressure while storing a wafer therein so as to transfer the wafer between the atmospheric side and the vacuum side. The lock chamber 105 has a stage for loading two or more wafers in a vertically stacked state. The first vacuum transfer chamber 104 has a substantially rectangular planar shape having the interior thereof decompressed, and has wafers transferred therein.

Vacuum transfer intermediate chambers 111, 115 and 116 for transferring wafers between a second, third and fourth vacuum transfer chambers 110, 112 and 113 are connected to three sides of the first vacuum transfer chamber 104 excluding the side connected to the lock chamber 105. In other words, on one side of the vacuum transfer intermediate chamber 111 is connected to the first vacuum transfer chamber 104, and on the other side thereof is connected to a second vacuum transfer chamber 110. The planar shape of the second vacuum transfer chamber 110 also is substantially rectangular, and on one side thereof is connected to a single vacuum processing chamber 103. Further, the third vacuum transfer chamber 112 is connected to the vacuum transfer intermediate chamber 115, wherein a single vacuum processing chamber 103 is connected to one side and a vacuum transfer intermediate chamber 117 for communicating with a fifth vacuum transfer chamber 103 is connected to another side of the third vacuum transfer chamber 112. Similarly, on another side of the first vacuum transfer chamber 104 is connected a vacuum transfer intermediate chamber 116 for communicating with a fourth vacuum transfer chamber 113, and a single vacuum processing chamber 103 is connected to the fourth vacuum transfer chamber 113. Moreover, a fifth vacuum transfer chamber 114 is connected to the other end of the vacuum transfer intermediate chamber 117, and a vacuum processing chamber 103 is arranged on the chamber 114.

In the present embodiment, the planar shape of the respective vacuum transfer chambers is substantially rectangular, but it can be triangular or any other polygonal shape, or can be spherical. Each vacuum transfer intermediate chamber has a stage for loading two or more wafers stacked vertically, similar to the lock chamber 105. The vacuum block 102 according to the present arrangement is a container capable of having the whole inner pressure thereof decompressed and maintained at a high degree of vacuum.

The first vacuum transfer chamber 104, the second vacuum transfer chamber 110, the third vacuum transfer chamber 112, the fourth vacuum transfer chamber 113 and the fifth vacuum transfer chamber 114 have their interior formed as transfer chambers. Each transfer chamber has a vacuum transfer robot 108 for transferring wafers in vacuum between the lock chamber 105 and the vacuum processing chambers 103 or the vacuum transfer intermediate chambers 111 disposed at the center area. The vacuum transfer robot 108 within the first vacuum transfer chamber 104 loads wafers on two arms, respectively, for carrying wafers into and out of the lock chamber 105 or any one of the vacuum transfer intermediate chambers 111, 115 and 116. The vacuum transfer robot 108 within the second vacuum transfer chamber 110 loads wafers on two arms, respectively, for carrying wafers into and out of the vacuum processing chamber 103 or the vacuum transfer intermediate chamber 111. The vacuum transfer robots disposed in other vacuum transfer chambers work in the same manner. Further, passages are disposed for communicating the respective vacuum processing chambers 103, the lock chamber 105, the vacuum transfer intermediate chambers 111, 115, 116 and 117 and respective vacuum transfer chambers 104, 110, 112, 113 and 114 and being airtightly sealed or opened via valves 120, 120, 120 and so on, and these passages are opened and closed via valves 120.

Next, we will describe an outline of the wafer transfer process according to the vacuum processing method of a wafer for processing a wafer via the vacuum processing system 100 arranged as above.

A plurality of semiconductor wafers stored in a cassette placed on any one of the plurality of cassette stands 107, 107 and 107 are subjected to processing either via the decision of a control unit (not shown) for controlling the operation of the vacuum processing system 100 or via a command from a control unit (not shown) of a manufacturing line in which the vacuum processing system 100 is installed. First, the atmospheric transfer robot 109 having received a command from the control unit takes out a specific wafer from a cassette, and transfers the wafer to the lock chamber 105.

The lock chamber 105 to which the wafer is transferred and stored has a valve 120 connected thereto closed in an airtight manner with the transferred wafer stored in the chamber, and the chamber is decompressed to a predetermined pressure. The lock chamber 105 can store two or more wafers. Thereafter, the valve 120 disposed on the side facing the first vacuum transfer chamber 104 is opened, by which the lock chamber 105 is communicated with the first vacuum transfer chamber 104, and the vacuum transfer robot 108 extends its arm into the lock chamber 105 and transfers the wafer in the lock chamber 105 toward the first vacuum transfer chamber 104. The first vacuum transfer chamber 104 can have two or more wafers stored therein. The vacuum transfer robot 108 transfers the wafer loaded on its arm to any of the vacuum transfer intermediate chambers 111, 115 or 116 determined in advance when the wafer is taken out of the cassette.

According to the present embodiment, one of the multiple valves 120 is selected to be opened and closed. In other words, when the wafer is transferred to the vacuum transfer intermediate chamber 111, the valves 120 and 120 opening and closing the passages between the vacuum transfer intermediate chamber 111 and the first vacuum transfer chamber 104 or the second vacuum transfer chamber 110 are closed, and the vacuum transfer intermediate chamber 111 is sealed. Thereafter, the valve 120 opening and closing the passage between the vacuum transfer intermediate chamber 111 and the second vacuum transfer chamber 110 is opened, and the vacuum transfer robot 108 disposed in the second vacuum transfer chamber 110 extends its arm to carry the wafer into the second vacuum transfer chamber 110. Next, after the valve 120 opening and closing the passage between the second vacuum transfer chamber 110 and the vacuum transfer intermediate chamber 111 is closed, the vacuum transfer robot 108 transfers the wafer loaded on the arm into the vacuum processing chamber 103 by opening the valve 120 opening and closing the passage between the vacuum processing chamber 103 and the second vacuum transfer chamber 110. Which vacuum processing chamber 103 is to be used for processing the respective wafers is determined in advance when the wafers are taken out of the cassettes. Further, the wafer transferred to the vacuum transfer intermediate chamber 115 is carried toward the vacuum processing chamber 103 or the fifth vacuum transfer chamber 114 via the vacuum transfer robot 108 disposed in the third vacuum transfer chamber 112 in a similar manner as mentioned earlier, and thereafter transferred to a subsequent vacuum processing chamber 103. Further, the wafer transferred to the vacuum transfer intermediate chamber 116 is transferred via the vacuum transfer robot 108 disposed in the fourth vacuum transfer chamber 113 to the vacuum processing chamber 103 in a similar manner.

After the wafers are transferred to the respective vacuum processing chambers 103, the valves 120 opening and closing the passages between the respective vacuum processing chambers 103 and the respective vacuum transfer chambers 110, 112, 113 and 114 are closed, and the respective vacuum processing chambers 103 are sealed. Thereafter, processing gases are introduced to the respective vacuum processing chambers 103, and when the pressure within each vacuum processing chamber 103 reaches a predetermined pressure, the wafers are subjected to processing.

In any of the vacuum processing chambers 103, when the termination of wafer processing is detected, the valves 120 opening and closing the passages between the respective vacuum processing chambers 103 and the second vacuum transfer chamber 110, the third vacuum transfer chamber 112, the fourth vacuum transfer chamber 113 and the fifth vacuum transfer chamber 114 are opened, and the vacuum transfer robot 108 within the respective transfer chamber sends the processed wafer to the lock chamber 105 via an opposite route as when the wafer was transferred to the vacuum processing chamber 103. When the wafer is transferred to the lock chamber 105, the valve 120 opening and closing the passage between the lock chamber 105 and the first vacuum transfer chamber 104 is closed so as to airtightly seal the transfer chamber of the first vacuum transfer chamber 104, and the pressure within the lock chamber 105 is raised to atmospheric pressure.

Thereafter, the valve 120 on the inner side of the housing 106 is opened to communicate the inner side of the lock chamber 105 with the inner side of the housing 106 in atmospheric pressure, and the atmospheric transfer robot 109 transfers the wafer from the lock chamber 105 to the original position in the original cassette.

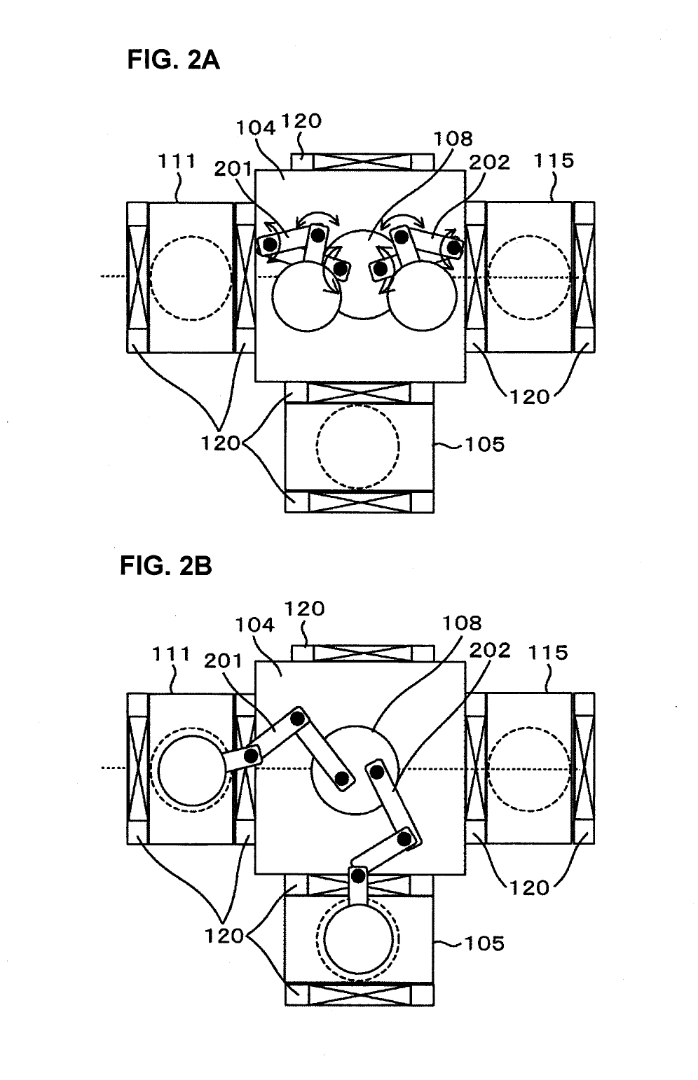

FIGS. 2A and 2B are enlarged views of the first vacuum transfer chamber 104 illustrated in FIG. 1. The vacuum transfer robot 108 has a first arm 201 and a second arm 202 for transferring the wafers. The robot has two arms according to the present embodiment, but the number of arms can be three or four.

Each arm 201 and 202 has a structure in which multiple beam members have both ends thereof connected via joints. Each arm 201 and 202 is designed so that multiple beam members have both ends thereof axially supported in pivotable manner, so that the respective arms 201 and 202 are capable of pivoting and expanding or shrinking in both the vertical and horizontal directions independently around the axes on the base ends of the arms, respectively. According to this arrangement, it becomes possible to independently control the carrying in and carrying out of multiple wafers, and to enhance the transfer performance by accessing multiple transfer destinations in parallel or carrying in and carrying out two wafers simultaneously.

FIG. 2A shows a state in which wafers are transferred into the first vacuum transfer chamber 104 from separate locations via arms 201 and 202. FIG. 2B shows a state in which the first arm 201 transfers a wafer to the vacuum transfer intermediate chamber 111 and the second arm 202 transfers a wafer to the lock chamber 105 simultaneously or in parallel. The timing of transfer of the wafers via the respective arms is not necessarily simultaneous, and the arms can be controlled independently.

By adopting a vacuum processing system 100 arranged as above, the wafer processing efficiency per footprint can be enhanced. This is due to the following reasons. In the case of the limited transfer rate mentioned earlier, when the time required for transferring the wafer into the vacuum processing chamber 103 (the time from the state where the vacuum transfer robot 108 holding the wafer is at standby state in front of the vacuum processing chamber 103 to when the transfer of the wafer into the vacuum processing chamber 103 is completed and the valve 120 is closed) is compared with the time required for transferring the wafer into the vacuum transfer intermediate chamber 111 (the time from the state where the vacuum transfer robot 108 holding the wafer is at standby state in front of the transfer intermediate chamber 111 to when the transfer of the wafer into the transfer intermediate chamber 111 is completed and the valve 120 is closed), the transfer time for transferring the wafer into the vacuum transfer intermediate chamber 111 is shorter. Therefore, when assuming that the present embodiment comprises a first vacuum transfer chamber 104 having no vacuum processing chambers 103 connected thereto, and the other vacuum transfer chambers respectively have a single vacuum processing chamber 103 connected thereto, it becomes possible to prevent the transfer time of the first vacuum transfer chamber 104 from becoming the bottleneck of the overall transfer time of the vacuum processing system 100 and to prevent the deterioration of processing efficiency of the vacuum processing system 100. Therefore, the arrangement according to the present embodiment enables to improve the wafer processing efficiency per footprint.

According further to the first preferred embodiment of the present invention, the vacuum processing chambers 103 and the vacuum transfer chambers 104, 110, 112, 113 or 114, or the lock chamber 105 (or the vacuum transfer intermediate chambers 111, 115, 116 or 117) and the vacuum transfer chambers 104, 110, 112, 113 or 114 are communicated via valves 120 that open and close in an exclusive manner, so that it becomes possible to suppress the generation of particles and the occurrence of cross-contamination effectively.

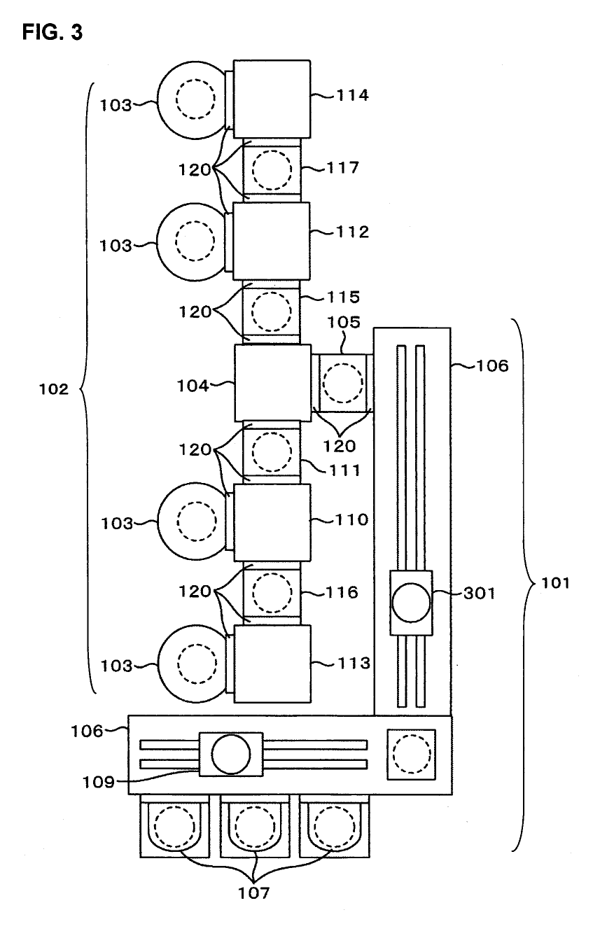

FIG. 3 illustrates the overall arrangement of a vacuum processing system including a plurality of vacuum processing chambers according to a second embodiment of the present invention. According to the second embodiment, a plurality of vacuum processing chambers 103, 103, 103 and 103 are arranged in series, and a lock chamber 105 is disposed at the center thereof. Therefore, unlike the first embodiment illustrated in FIG. 1, a second atmospheric transfer robot 301 is disposed in addition to the atmospheric transfer robot 109 in the atmospheric block 101 in a direction perpendicular to the atmospheric transfer robot 109. A lock chamber 105 for transferring wafers between the atmospheric block 101 and the vacuum block 102 is connected to the opposite end of the second atmospheric transfer robot 301. The atmospheric block 101 is connected via the lock chamber 105 to the vacuum block 102. The wafer is transferred from the lock chamber 105 to the first vacuum transfer chamber 104 via a vacuum transfer robot 108 disposed in the first vacuum transfer chamber 104. Further, the transfer destination of the wafer is controlled via a control unit (not shown), and the wafer is transferred to the predetermined direction, either toward the vacuum transfer intermediate chamber 111 or toward the vacuum transfer intermediate chamber 115 adjacent to the first vacuum transfer chamber 104. The wafer transferred to the vacuum transfer intermediate chamber 111 is transferred via the vacuum transfer robot 108 disposed in the second vacuum transfer chamber 110 to the second vacuum transfer chamber 110. Thereafter, the wafer is transferred via the vacuum transfer robot 108 to the vacuum processing chamber 103 or the vacuum transfer intermediate chamber 116 connected to the second vacuum transfer chamber 110. Further, the wafer transferred to the vacuum transfer intermediate chamber 116 is carried into the vacuum processing chamber 103 and processed therein. Similarly, the wafer transferred to the vacuum transfer intermediate chamber 115 is transferred sequentially to the third vacuum transfer chamber 112 and to the vacuum processing chamber 103 connected to the fifth vacuum transfer chamber 114, and processed therein.

When it is detected that the processing of the wafer is completed, the valve 120 opening and closing the passages between the respective vacuum processing chambers 103 and the second vacuum transfer chamber 110, the third vacuum transfer chamber 112, the fourth vacuum transfer chamber 113 and the fifth vacuum transfer chamber 114 connected thereto is opened, and the vacuum transfer robot 108 transfers the processed wafer toward the lock chamber 105 via the opposite route as when the wafer was carried into the vacuum processing chambers 103. When the wafer is carried into the lock chamber 105, the valve 120 opening and closing the passage between the lock chamber 105 and the first vacuum transfer chamber 104 is closed so as to airtightly seal the first vacuum transfer chamber 104, and the pressure within the lock chamber 105 is raised to atmospheric pressure.

Thereafter, the valve 120 on the inner side of the housing 106 is opened to communicate the interior of the lock chamber 105 with the interior of the housing 106, the wafer is transferred from the second atmospheric transfer robot 301 to the atmospheric transfer robot 109, and the atmospheric transfer robot 109 transfers the wafer to the original cassette position in the original cassette.

As described, according to both the first and second embodiments of the present invention, no vacuum processing chamber is connected to the first vacuum transfer chamber 104 connected to the lock chamber 105, and at a subsequent section of the first vacuum transfer chamber 104, each vacuum transfer chamber 110, 112, 113 and 114 connected via vacuum transfer intermediate chambers 111, 115, 116 and 117 has a single vacuum processing chamber 103 connected thereto, so that even in the case of a limited transfer rate, the system is comprised and controlled so as to prevent the first vacuum transfer chamber 104 from becoming the bottleneck of the whole wafer transfer process.

According to the vacuum processing system described as above, the wafer processing efficiency per footprint becomes high. This is due to the same reasons as mentioned earlier with respect to the first embodiment illustrated in FIG. 1.

Further according to the present embodiment, the vacuum processing chambers and the vacuum transfer chambers or the lock chamber 105 (or the vacuum transfer intermediate chambers) and the vacuum transfer chambers are communicated via valves 120 opening and closing the passages in an exclusive manner, so as to prevent the generation of particles and the occurrence of cross-contamination effectively.

What is claimed is:

1. A vacuum processing system of a semiconductor processing substrate comprising:
an atmospheric transfer chamber having a plurality of cassette stands arranged on a front side thereof for transferring a wafer stored in a cassette disposed on one of the plurality of cassette stands;
a lock chamber arranged on a rear side of the atmospheric transfer chamber for storing in an interior thereof the wafer transferred from the atmospheric transfer chamber; and
a first vacuum transfer chamber connected to a rear side of the lock chamber to which the wafer from the lock chamber is transferred;
wherein the first vacuum transfer chamber does not have any vacuum processing chamber connected thereto for processing wafers transferred to the first vacuum transfer chamber and has a plurality of transfer intermediate chambers connected thereto, and the plurality of transfer intermediate chambers have subsequent vacuum transfer chambers connected thereto; and
wherein the wafers stored in the cassette are transferred from the cassette via the lock chamber to the first vacuum transfer chamber to be processed in each of the subsequent vacuum processing chambers, which are further transferred via any of the plurality of transfer intermediate chambers connected to the first vacuum transfer chamber to the plurality of subsequent vacuum transfer chambers, and the respective wafers transferred to the plurality of subsequent vacuum transfer chambers other than the first vacuum transfer chamber are transferred to the respective vacuum processing chambers connected to each of the plurality of vacuum transfer chambers and processed therein.

2. The vacuum processing system of a semiconductor processing substrate according to claim 1, wherein
only a single vacuum processing chamber is connected to each of the plurality of subsequent vacuum transfer chambers.

3. The vacuum processing system of a semiconductor processing substrate according to claim 1, wherein
transfer robots are disposed in the interior of each of the respective first and subsequent vacuum transfer chambers, and each transfer robot is composed of a plurality of arms having beam members as multiple joints capable of moving independently around respective axes.

4. A vacuum processing method of a semiconductor processing substrate for processing a semiconductor processing substrate using a vacuum processing system of a semiconductor processing substrate comprising:
an atmospheric transfer chamber having a plurality of cassette stands arranged on a front side thereof for transferring a wafer stored in a cassette disposed on one of the plurality of cassette stands;
a lock chamber arranged on a rear side of the atmospheric transfer chamber for storing in an interior thereof the wafer transferred from the atmospheric transfer chamber; and
a first vacuum transfer chamber connected to a rear side of the lock chamber to which the wafer from the lock chamber is transferred;
wherein the first vacuum transfer chamber does not have any vacuum processing chamber connected thereto for processing wafers transferred to the first vacuum transfer chamber and has a plurality of transfer intermediate chambers connected thereto, and the plurality of transfer intermediate chambers have subsequent vacuum transfer chambers connected thereto; and
wherein the vacuum processing method of the semiconductor processing substrate comprises transferring wafers stored in the cassette to a the lock chamber, transferring the wafers transferred into the lock chamber to the first vacuum transfer chamber, and further transferring the same to each of the plurality of subsequent vacuum transfer chambers via any of the plurality of transfer intermediate chambers connected subsequently to the first vacuum transfer chamber, and thereafter, transferring the respective wafers transferred to the plurality of vacuum transfer chambers to the respective vacuum processing chambers each connected to the respective vacuum transfer chambers.
